(19) United States
(12) Patent Application Publication
(10) Pub. No.: US 2011/0156531 A1
(43) Pub. Date: Jun. 30, 2011

(54) ACOUSTIC WAVE DEVICE

(75) Inventors: Daisuke TAMAZAKI, Nagaokakyo-shi (JP); Motoji TSUDA, Nagaokakyo-shi (JP); Hisashi YAMAZAKI, Nagaokakyo-shi (JP); Masahiko SAEKI, Nagaokakyo-shi (JP); Harunobu HORIKAWA, Nagaokakyo-shi (JP)

(73) Assignee: MURATA MANUFACTURING CO., LTD., Nagaokakyo-shi (JP)

(21) Appl. No.: 12/973,958

(22) Filed: Dec. 21, 2010

(30) Foreign Application Priority Data
Dec. 25, 2009 (JP) 2009-294792

(51) Int. Cl. H03H 9/25

(52) U.S. Cl. 310/313 C; 310/313 B

(57) ABSTRACT

An acoustic wave device includes a piezoelectric substrate and an IDT electrode disposed thereon. The IDT electrode includes a metal laminate. The metal laminate includes a first metal layer made of Al or an Al-based alloy, a second metal layer made of a metal or alloy different from that used in the first metal layer, a Cu layer, and a Ti layer. The Cu layer and the Ti layer are disposed between the first and second metal layers. The Cu layer is located on the first metal layer side.

### BACKGROUND OF THE INVENTION

1. Field of the Invention

The present invention relates to acoustic wave devices used for, for example, band-pass filters and resonators, and particularly to an acoustic wave device including an IDT electrode including a metal laminate including a metal layer made of Al or an Al alloy.

2. Description of the Related Art

Surface acoustic wave devices have been widely used as filters and resonators for mobile communication devices.

For example, Japanese Unexamined Patent Application Publication No. 2006-20134 discloses a surface acoustic wave element 101 shown in FIG. 9. The surface acoustic wave element 101 includes a piezoelectric substrate 102 and an IDT electrode 103 disposed thereon. The IDT electrode 103 includes a lower Ti layer 104, an intermediate metal layer 105 made of Mo, W, or an alloy including Mo and/or W, an upper Ti layer 106, and an upper conductive layer 107 made of Al or an Al alloy, these layers being arranged on the piezoelectric substrate 102 in that order. The lower Ti layer 104 has a thickness of about 10 nm to about 30 nm, the intermediate metal layer 105 has a thickness of about 30 nm to about 65 nm, and the upper Ti layer 106 has a thickness of about 10 nm to about 30 nm. This increases the dielectric strength of the surface acoustic wave element 101.

The surface acoustic wave element 101 disclosed in Japanese Unexamined Patent Application Publication No. 2006-20134 has high dielectric strength due to the deposition of the metal layers, each having a specific thickness. When subjecting the surface acoustic wave element 101 to a dielectric strength test or to a high-temperature atmosphere during reflow soldering, Ti in the lower Ti layer 104 or the upper Ti layer 106 diffuses into the intermediate metal layer 105 and the upper conductive layer 107, which are next to the lower Ti layer 104 or the upper Ti layer 106. Therefore, the lower Ti layer 104 and the upper Ti layer 106 are likely to include defects. This causes the interdiffusion of Mo or W in the intermediate metal layer 105, which is located under the upper Ti layer 106, and Al in the upper conductive layer 107, which is located on the upper Ti layer 106. Therefore, there is a problem in that electrode fingers of the IDT electrode 103 have increased resistance, and therefore, the surface acoustic wave element 101 has deteriorated frequency properties. Furthermore, there is a problem in that Ti in the upper Ti layer 106 diffuses into the upper conductive layer 107 during the dielectric strength test which causes a fluctuation in frequency.

### SUMMARY OF THE INVENTION

To overcome the problems described above, preferred embodiments of the present invention provide an acoustic wave device in which the interdiffusion of metal layers defining electrodes and the increase in resistance of electrode fingers are prevented even if the acoustic wave device is exposed to elevated temperatures and in which frequency properties and dielectric strength are not deteriorated.

An acoustic wave device according to a preferred embodiment of the present invention includes a piezoelectric substrate and an IDT electrode disposed on the piezoelectric substrate. The IDT electrode includes a metal laminate. The metal laminate preferably includes a first metal layer made of Al or an Al-based alloy, a second metal layer made of a metal or alloy different from that used in the first metal layer, a Cu layer, and a Ti layer, for example. The Cu layer and the Ti layer are preferably disposed between the first and second metal layers. The Cu layer is preferably located on the first metal layer side.

In the acoustic wave device, the Al-based alloy preferably primarily includes Al and at least one material selected from the group consisting of Cu, Si, Mg, Ti, Ag, Ni, Zn, Au, and Cr, for example. This enables the acoustic wave device to have increased dielectric strength.

In the acoustic wave device, the second metal layer is preferably made of at least one material selected from the group consisting of Pt, Au, Ag, Ta, W, Mo, Pd, Ni, and Cr or an alloy primarily including at least one of these metals, for example. This enables the acoustic wave device to have further increased dielectric strength.

In the acoustic wave device, the Ti layer preferably has a thickness that is about 1.5% or less of the wavelength of an acoustic wave, for example. This prevents the frequency characteristic of the acoustic wave device from being deteriorated.

The acoustic wave device may be a surface acoustic wave device or a boundary acoustic wave device. The acoustic wave device further preferably includes a dielectric layer extending over the IDT electrode to function as a boundary acoustic wave device and using a boundary acoustic wave propagating along the interface between the dielectric layer and the piezoelectric substrate.

In a acoustic wave device according to a preferred embodiment of the present invention, for example, a Cu layer and a Ti layer are preferably disposed between a first metal layer made of Al or an Al-based alloy and a second metal layer made of a metal or alloy different from that used in the first metal layer and the Cu layer is located on the first metal layer side. Therefore, the interdiffusion of Al in the first metal layer and the metal included in the second metal layer are effectively prevented even if the acoustic wave device is exposed to an elevated temperature. This prevents the frequency characteristic of the acoustic wave device from being deteriorated. Furthermore, Ti in the Ti layer is prevented from diffusing into the first metal layer. Therefore, the resistance of the electrode fingers is unlikely to be deteriorated and variations in frequency of the acoustic wave device are prevented during a dielectric strength test.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a fragmentary front sectional view of an acoustic wave device according to a first preferred embodiment of the present invention.

FIG. 1B is a plan view illustrating the electrode structure of the acoustic wave device according to the first preferred embodiment of the present invention.

FIG. 2 is a front sectional view of a multilayer structure prepared in Comparative Example 1.

FIG. 3 is a front sectional view of a multilayer structure prepared in Example 1.

FIG. 4 is a graph illustrating the relationship between the sheet resistance and heating conditions of the multilayer structures, shown in FIG. 2 or 3, subjected to a heating test.

FIG. 5 is a fragmentary front sectional view of an acoustic wave device according to a second preferred embodiment of the present invention.

FIG. 6 is a schematic plan view illustrating a method of performing a dielectric strength test.

FIG. 7 is a graph illustrating a spectrum showing the transmission characteristic of an acoustic wave device according to the second preferred embodiment of the present invention.

FIG. 8 is a graph illustrating results obtained by subjecting an acoustic wave device prepared in Example 2 and an acoustic wave device prepared in Comparative Example 2 to a dielectric strength test.

FIG. 9 is a front sectional view of a conventional acoustic wave device.

### DETAILED DESCRIPTION OF THE PREFERRED EMBODIMENTS

Preferred embodiments of the present invention will be described in detail with reference to the attached drawings.

### First Preferred Embodiment

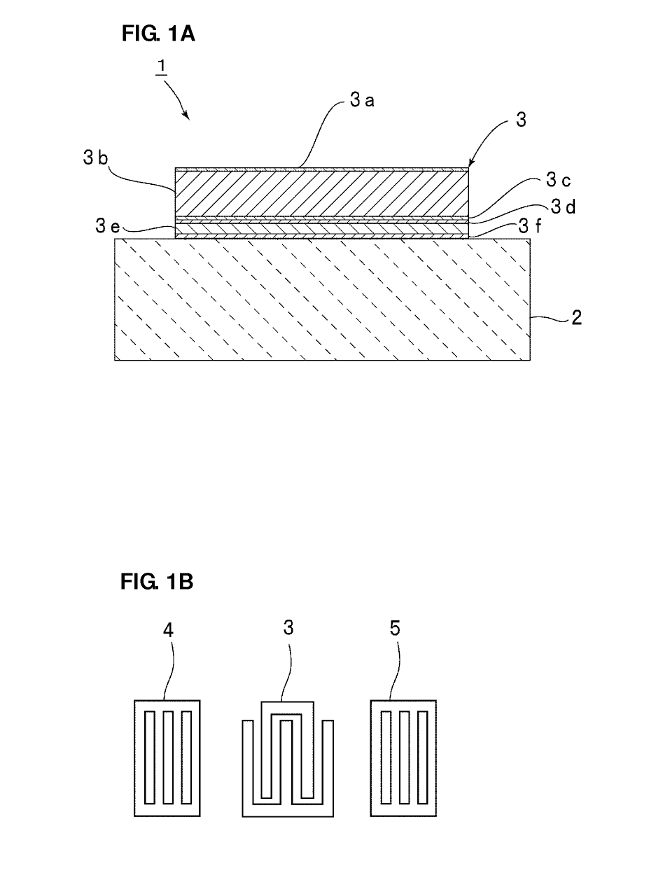

FIG. 1A is a fragmentary front sectional view of an acoustic wave device 1 according to a first preferred embodiment of the present invention. FIG. 1B is a plan view illustrating the electrode structure of the acoustic wave device 1.

The acoustic wave device 1 is a surface acoustic wave device that utilizes surface acoustic waves.

The acoustic wave device 1 includes a piezoelectric substrate 2 and an IDT electrode 3 disposed on the piezoelectric substrate 2. In this preferred embodiment, the piezoelectric substrate 2 is preferably made of LiNbO₃, for example. The piezoelectric substrate 2 may be made from a single crystal of a piezoelectric material, such as LiTaO₃ or quartz, for example. Alternatively, the piezoelectric substrate 2 may be made of a piezoelectric ceramic, such as lead zirconate titanate (PZT), for example.

With reference to FIG. 1B, a first reflector 4 and a second reflector 5 are arranged on both sides of the IDT electrode 3 in the propagation direction of a surface acoustic wave. In the acoustic wave device 1, the first and second reflectors 4 and 5 and the IDT electrode 3 define a surface acoustic wave resonator.

The IDT electrode 3 includes a pair of interdigital sub-electrodes each including a plurality of electrode fingers. The electrode fingers of one of the interdigital sub-electrodes interdigitate with those of the other interdigital sub-electrode. The IDT electrode 3 and the first and second reflectors 4 and 5 include metal laminates.

With reference to FIG. 1A, the IDT electrode 3 includes a metal laminate including a plurality of stacked metal layers. In particular, the IDT electrode 3 preferably includes an upper Ti layer 3a, a first metal layer 3b, a Cu layer 3c, a lower Ti layer 3d, a second metal layer 3e made of Pt, and a Ni—Cr layer 3f that are arranged in that order from the top.

The upper Ti layer 3a preferably has a thickness of about 10 nm, for example. The first metal layer 3b preferably has a thickness of about 130 nm, for example. The Cu layer 3c preferably has a thickness of about 10 nm, for example. The lower Ti layer 3d preferably has a thickness of about 10 nm, for example. The second metal layer 3e preferably has a thickness of about 40 nm, for example. The Ni—Cr layer 3f preferably has a thickness of about 10 nm, for example.

The first metal layer 3b is preferably made of an Al-based alloy including ten parts by weight of Cu per 100 parts by weight of Al, for example. The term “Al-based alloy” as used herein refers to an alloy primarily including Al.

The Ni—Cr layer 3f functions as an adhesive layer for securing the adhesion of the IDT electrode 3 to the piezoelectric substrate 2, which is preferably made of LiNbO₃, for example. The Ni—Cr layer 3f is not necessarily essential.

In the IDT electrode 3, the first metal layer 3b, which preferably has a thickness of about 130 nm, for example, and the second metal layer 3e, which preferably has a thickness of about 40 nm, for example, function as principal electrode layers. This allows the acoustic wave device 1 to have desired resonant properties. That is, desired resonant properties are obtained by the mass loading effect of the first metal layer 3b and the second metal layer 3e. The first metal layer 3b contributes to an increase in conductivity.

The Cu layer 3c and the lower Ti layer 3d are preferably disposed between the first metal layer 3b and the second metal layer 3e.

The upper Ti layer 3a, the first metal layer 3b, the Cu layer 3c, the lower Ti layer 3d, the second metal layer 3e, and the Ni—Cr layer 3f are preferably formed by vapor deposition, for example.

That is, the IDT electrode 3 can preferably be formed such that the piezoelectric substrate 2 is prepared and Ni—Cr, Pt, Ti, Cu, the Al—Cu alloy, and Ti are deposited on the piezoelectric substrate 2 in that order by vapor deposition.

After the IDT electrode 3 is formed, the acoustic wave device 1 is exposed to elevated temperatures in some cases. In particular, the acoustic wave device 1 is exposed to about 270° C., for example, when the acoustic wave device 1 is mounted on a printed circuit board by, for example, reflow soldering. Therefore, the IDT electrode 3 must not deteriorate at elevated temperatures.

When the acoustic wave device 1 is exposed to an elevated temperature, Al in the first metal layer 3b may diffuse into the second metal layer 3e and Pt in the second metal layer 3e may diffuse into the first metal layer 3b. The lower Ti layer 3d functions as a diffusion-preventing layer to prevent such interdiffusion.

In this preferred embodiment, the Cu layer 3c is preferably disposed on the first metal layer 3b side. This prevents the diffusion of Ti in the lower Ti layer 3d into the first metal layer 3b at elevated temperatures to prevent defects from occurring in the lower Ti layer 3d. Thus, the interdiffusion of Al and Pt is effectively prevented.

That is, Ti in the lower Ti layer 3d migrates toward the first metal layer 3b at an elevated temperature. However, the Cu layer 3c prevents the diffusion of Ti. Therefore, the lower Ti layer 3d is unlikely to be defective. The interdiffusion of Al and Pt can be effectively prevented. Thus, the deterioration of resonant properties and frequency properties of the acoustic wave device 1 are prevented. Since Ti in the lower Ti layer 3d is prevented from diffusing into the first metal layer 3b during a dielectric strength test, a fluctuation in frequency is prevented during the dielectric strength test.

### Second Preferred Embodiment

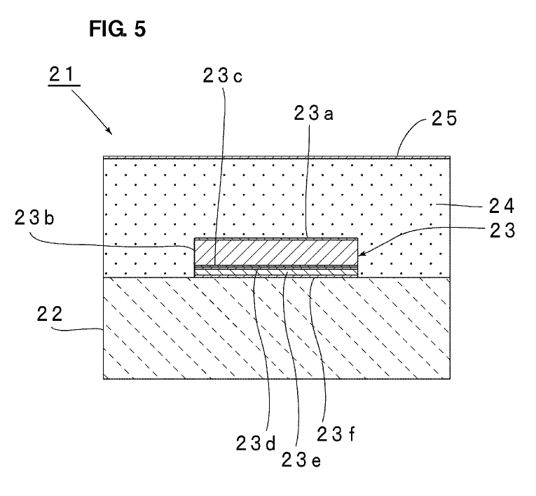

FIG. 5 is a fragmentary front sectional view of an acoustic wave device 21 according to a second preferred embodiment of the present invention.

The acoustic wave device 21 is preferably a surface acoustic wave device that utilizes surface acoustic waves. The acoustic wave device 21 includes a piezoelectric substrate 22 preferably made of LiNbO₃, for example, and an IDT electrode 23 disposed on the piezoelectric substrate 22. Reflectors are arranged on both sides of the IDT electrode 23 in the propagation direction of a surface acoustic wave. An electrode structure including the IDT electrode 23 and the reflectors is substantially the same as described with respect to the acoustic wave device 1 shown in FIG. 1B.

Preferably, the IDT electrode 23 and the reflectors each include a metal laminate including a plurality of stacked metal layers. The metal laminate preferably has substantially the same configuration as that described for the IDT electrode 3. In the metal laminate, for example, an upper Ti layer 23a, a first metal layer 23b, a Cu layer 23c, a lower Ti layer 23d, a second metal layer 23e made of Pt, and a Ni—Cr layer 23f are preferably arranged in that order from the top.

In this preferred embodiment, the acoustic wave device 21 further includes a temperature property-improving layer 24 extending over the IDT electrode 23 and the reflectors. The temperature property-improving layer 24 is preferably made of silicon dioxide, for example. The acoustic wave device 21 preferably further includes a protective layer 25, made of silicon nitride, for example, that overlies the temperature property-improving layer 24.

In the IDT electrode 23, the Cu layer 23c and the lower Ti layer 23d are preferably arranged between the first metal layer 23b and the second metal layer 23e. The Cu layer 23c is located on the first metal layer 23b side. As in the first preferred embodiment, defects are unlikely to occur in the lower Ti layer 23d even if the acoustic wave device 21 is exposed to elevated temperatures. Therefore, a change or increase in resistance of the IDT electrode 23 is prevented, which results in stable frequency properties.

In the first preferred embodiment, the first metal layer 3b is preferably made of the Al-based alloy, for example. However, the first metal layer 3b may be made of an Al alloy including Al and another metal other than the Al-based alloy, for example. That is, the first metal layer 3b may preferably be made of an Al alloy which primarily includes Al and which further includes at least one material selected from the group consisting of Cu, Si, Mg, Ti, Ag, Ni, Zn, Au, and Cr, for example. Alternatively, the first metal layer 3b may preferably be made of Al, for example.

The second metal layer 3e is preferably made of Pt. However, the second metal layer 3e may be made of a metal other than Pt or an alloy primarily including Pt. That is, the second metal layer 3e may preferably be made of at least one material selected from the group consisting of Pt, Au, Ag, Ta, W, Mo, Pd, Ni, and Cr or an alloy primarily including at least one of these metals, for example.

Even if the first metal layer 3b and the second metal layer 3e are made of the metals or alloys described above, defects caused by the diffusion of Ti can be securely prevented from occurring in the lower Ti layer 3d because the Cu layer 3c is located on the first metal layer 3b side. This is common to the first and second preferred embodiments.

The thickness of the lower Ti layer 3d, which is disposed between the first metal layer 3b made of Al or the Al-based alloy and the second metal layer 3e, may preferably be about 1.5% or less of the wavelength of an acoustic wave. When the thickness of the lower Ti layer 3d is greater than about 1.5% of the wavelength of the acoustic wave, the acoustic wave device 1, which functions as a surface or boundary acoustic wave device, has significantly deteriorated properties. Therefore, the thickness thereof is preferably about 1.5% or less of the wavelength thereof.

In the second preferred embodiment, the temperature property-improving layer 24 is preferably made of silicon dioxide. Thus, the absolute value of the temperature coefficient of frequency TCF thereof is low.

The protective layer 25 may preferably be made of silicon dioxide, tantalum oxide, aluminum oxide, aluminum nitride, diamond-like carbon (DLC), titanium oxide, titanium nitride, or silicon carbide other than silicon nitride, for example.

The temperature property-improving layer 24 and/or the protective layer 25 may preferably include a laminate including a plurality of stacked insulating layers.

In the first and second preferred embodiments, each of the upper Ti layer 3a and the upper Ti layer 23a preferably occupy a top position. However, the upper Ti layer 3a and the upper Ti layer 23a are not necessarily essential.

In the first and second preferred embodiments, the acoustic wave device 1 and the acoustic wave device 21 are described preferably in the context of a surface acoustic wave device, for example. Preferred embodiments of the present invention are also applicable to a boundary acoustic wave device which includes an IDT electrode, a dielectric layer extending over the IDT electrode, and a piezoelectric substrate and which utilizes a boundary acoustic wave propagating along the interface between the dielectric layer and the piezoelectric substrate.

Preferred embodiments of the present invention are applicable to not only resonators but also various acoustic wave devices such as band-pass filters and delay lines.

### Example 1

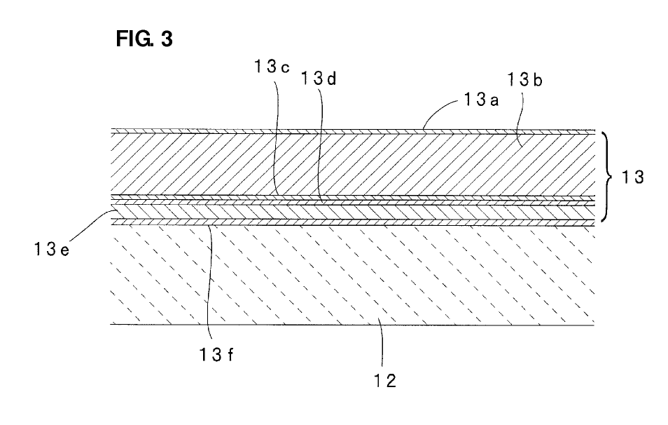

For the purpose of identifying the effect of preventing interdiffusion, multilayer structures corresponding to the acoustic wave device 1 according to the first preferred embodiment were prepared in substantially the same manner as that described in the first preferred embodiment, except that no IDT electrode was formed but a metal laminate was formed over the upper surface of a LiNbO₃ substrate 12 defining a piezoelectric substrate as shown in FIG. 3. In the metal laminate, the following layers were arranged in this order from the top: an upper Ti layer 13a, a first metal layer 13b made of the Al-based alloy described in the first preferred embodiment, a Cu layer 13c, a lower Ti layer 13d, a second metal layer 13e made of Pt, and a Ni—Cr layer 13f. These layers were each substantially identical in thickness to a corresponding one of those described in the first preferred embodiment. In the formation of the metal laminate, these layers were formed on the LiNbO₃ substrate 12 in that order by vapor deposition.

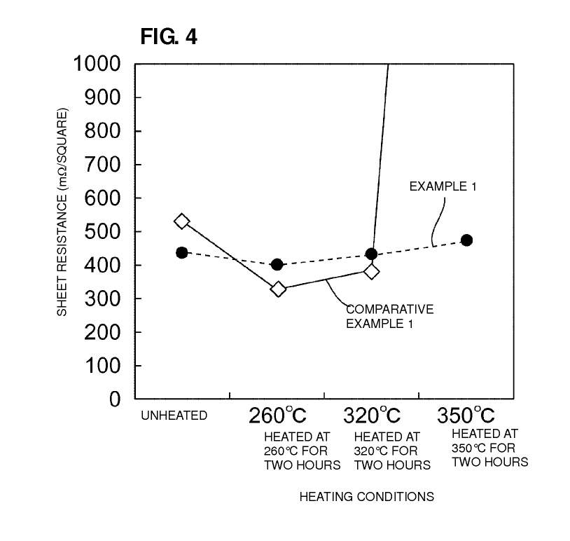

The multilayer structures were each heated at a temperature of about 260° C., about 320° C., or about 350° C. for about two hours. The unheated and heated multilayer structures were measured for sheet resistance with an eddy current-type sheet resistance meter. The measurement results are summarized in FIG. 4 and Table 1.

### Comparative Example 1

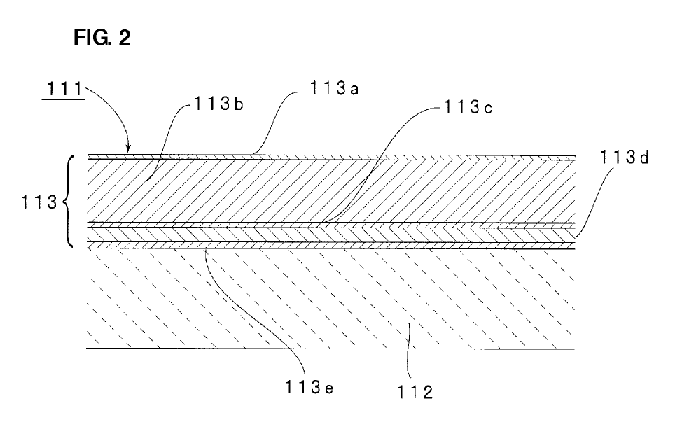

For comparison, multilayer structures 111 were prepared as shown in FIG. 2. The multilayer structures 111 each included a LiNbO₃ substrate 112 and a metal laminate 113 disposed thereon. The metal laminate 113 included an upper Ti layer 113a, an first metal layer 113b, a lower Ti layer 113c, a second metal layer 113d made of Pt, and a Ni—Cr layer 113e.

The upper Ti layer 113a had a thickness of about 10 nm. The first metal layer 113b had a thickness of about 130 nm. The lower Ti layer 113c had a thickness of about 10 nm. The second metal layer 113d had a thickness of about 40 nm. The Ni—Cr layer 113e had a thickness of about 10 nm. The composition of the first metal layer 113b and the Ni—Cr layer 113e were substantially identical to those described in the first preferred embodiment.

The multilayer structures were each heated at a temperature of about 260° C., about 320° C., or about 350° C. for about two hours. The unheated and heated multilayer structures were measured for sheet resistance with an eddy current-type sheet resistance meter. The measurement results are summarized in FIG. 4 and Table 1.

As shown in FIG. 4 and Table 1, the unheated metal laminate in Comparative Example 1 has a sheet resistance of about 528.5 mΩ/square, the metal laminate heated at about 260° C. for about two hours in Comparative Example 1 has a sheet resistance of about 324 mΩ/square, and the metal laminate heated at about 320° C. for about two hours in Comparative Example 1 has a sheet resistance of about 381 mΩ/square. This shows that heating causes a reduction in sheet resistance. The metal laminate heated at about 350° C. for about two hours in Comparative Example 1 has a sheet resistance of about 3,801 mΩ/square, which is an order of magnitude greater than that of the other metal laminates. These show that the metal laminates prepared in Comparative Example 1 significant vary in sheet resistance within a temperature range from about 25° C., which corresponds to room temperature, to about 320° C. and have a very high sheet resistance at about 350° C. or greater.

On the other hand, the metal laminates heated at about 260° C. or about 320° C. for about two hours in Example 1 have a sheet resistance slightly less than that of the metal laminate unheated in Example 1. The metal laminate heated at about 350° C. for about two hours in Example 1 is slightly greater in sheet resistance than the others.

| | Sheet resistance (mΩ/square) | | | |
|---|---|---|---|---|
| | | Heated at | Heated at | Heated at |
| | | 260° C. for | 320° C. for | 350° C. for |
| | Unheated | two hours | two hours | two hours |
| Example 1 | 434.4 | 396 | 429 | 473 |
| Comparative | 528.5 | 324 | 381 | 3,801 |
| Example 1 | | | | |

The reason that the metal laminates prepared in Comparative Example 1 vary in sheet resistance due to heating and are greatly deteriorated in sheet resistance at about 350° C. or higher is probably as described below.

The lower Ti layer 113c probably has defects due to the diffusion of Ti in the lower Ti layer 113c into the first metal layer 113b. The interdiffusion of Al in the first metal layer 113b and Pt in the second metal layer 113d probably occurs through the defects to cause an increase in sheet resistance. That is, the lower Ti layer 113c does not sufficiently function as a diffusion-preventing layer.

The metal laminates prepared in Example 1 include the Cu layer 13c, and therefore, the diffusion of Ti in the lower Ti layer 13d into the first metal layer 13b is prevented. This probably prevents defects from occurring in the lower Ti layer 13d.

Accordingly, deterioration in the sheet resistance in metal laminates prepared in Example 1 is effectively prevented even if the metal laminates are processed at an elevated temperature of about 350° C. or higher.

### Example 2

An acoustic wave device substantially identical to the acoustic wave device 21 according to the second preferred embodiment was prepared as described below.

A piezoelectric substrate 22 was prepared from 37°-rotated Y-cut X-propagation LiNbO₃. A resist pattern was formed on the piezoelectric substrate 22 so as to have openings for forming an IDT electrode 23 and reflectors. By vapor deposition, Ni—Cr, Pt, Ti, Cu, an Al—Cu alloy, and Ti were deposited on the insulating layer 22 through the openings in that order. The resist pattern was removed from the piezoelectric substrate 22 by a lift-off process, whereby the IDT electrode 23 and reflectors were formed. The IDT electrode 23 and reflectors each included an upper Ti layer 23a, an Al—Cu alloy layer 23b, a Cu layer 23c, a lower Ti layer 23d, a Pt layer 23e, and a Ni—Cr layer 23f.

The upper Ti layer 23a had a thickness of about 10 nm. The Al—Cu alloy layer 23b had a thickness of about 130 nm. The Cu layer 23c had a thickness of about 10 nm. The lower Ti layer 23d had a thickness of about 10 nm. The Pt layer 23e had a thickness of about 40 nm. The Ni—Cr layer 23f had a thickness of about 10 nm.

Silicon dioxide was deposited over the IDT electrode 23 and reflectors by sputtering, whereby a temperature property-improving layer 24, made of silicon dioxide, having a thickness of about 620 nm was formed. Silicon nitride was deposited on the temperature property-improving layer 24 by sputtering, whereby a protective layer 25, made of silicon nitride, having a thickness of about 20 nm was formed. The temperature property-improving layer 24 and the protective layer 25 had openings for forming electrode pads for external electrical connection.

The electrode pads were formed from metal laminates similar to the IDT electrode 23 so as to be connected to the IDT electrode 23.

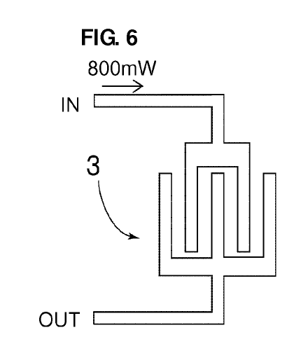

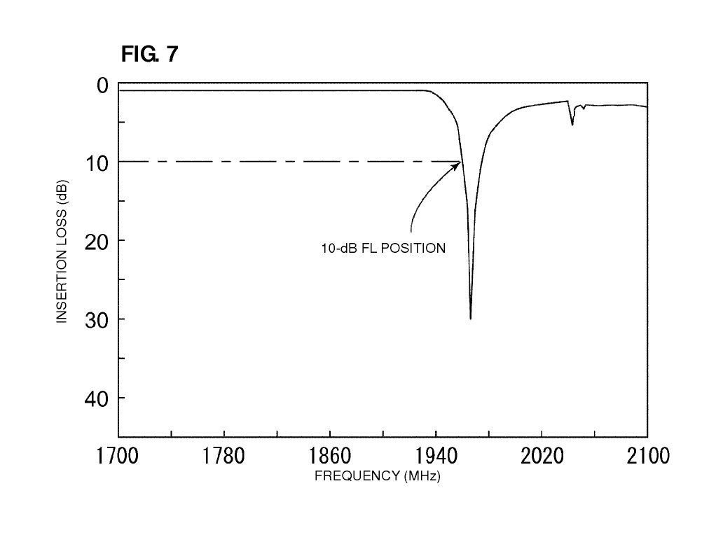

The acoustic wave device was subjected to a dielectric strength test such that bonding wires were connected to the electrode pads and a power of about 800 mW was applied to the IDT electrode 23 as shown in FIG. 6. FIG. 7 is a graph illustrating a spectrum showing the transmission characteristic of the acoustic wave device subjected to the dielectric strength test. The acoustic wave device was evaluated for dielectric strength on the basis of a 10-dB FL position in the spectrum, that is, a frequency position having an insertion loss about 10 dB less than that of a minimum insertion loss position.

In the dielectric strength test, the rate of change in frequency of the 10-dB FL position, that is, a 10-dB FL change rate was determined while a power of about 800 mW was being applied to the acoustic wave device. The 10-dB FL change rate is determined by the following equation:

10-dB FL change rate(ppm)={(10-dB FL frequency at test time t)−(initial 10-dB FL frequency)}/(initial 10-dB FL frequency)

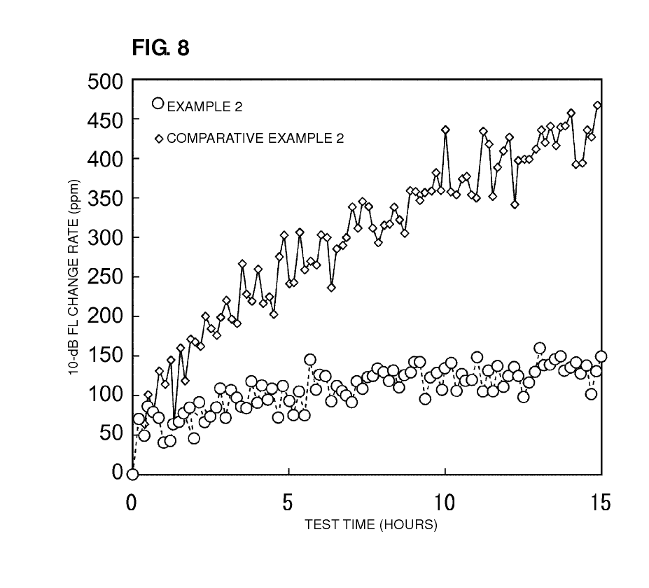

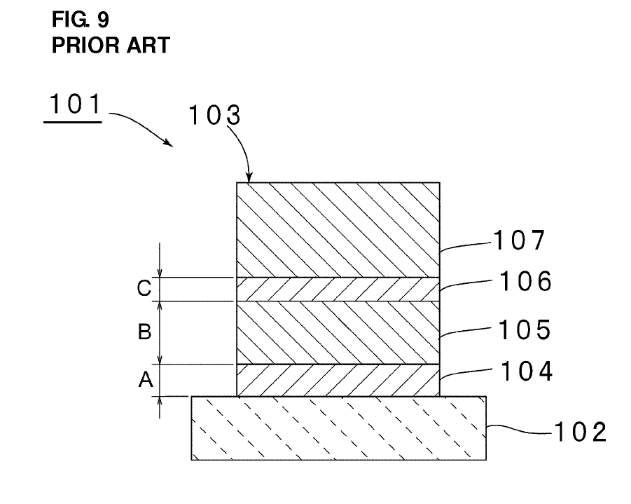

The test results are summarized in FIG. 8.

### Comparative Example 2

For comparison, an acoustic wave device was prepared in substantially the same manner as that described in the second preferred embodiment except that no Cu layer 23c was formed.

Electrode pads were formed in substantially the same manner as that described in Example 2. The acoustic wave device was subjected to substantially the same dielectric strength test as that described in Example 2. The test results are summarized in FIG. 8.

As shown in FIG. 8, the 10-dB FL change rate of the acoustic wave device of Comparative Example 2 significantly increases with time in the dielectric strength test. The 10-dB FL change rate thereof at a time of, for example, about 15 hours is about eight to nine times that at a time of about two hours.

In contrast, the 10-dB FL change rate of the acoustic wave device 21 of Example 2 varies very little for about 15 hours from the start of the dielectric strength test. This shows that the acoustic wave device 21 of Example 2 does not significantly vary in frequency characteristic.

In the acoustic wave device of Comparative Example 2, Ti in the lower Ti layer, which is disposed between the Al—Cu alloy layer and the Pt layer, probably diffuses into the Al—Cu alloy layer, which causes the frequency to shift higher. That is, the diffusion of Ti in the lower Ti layer into the Al—Cu alloy layer probably causes a variation in frequency characteristic.

In the acoustic wave device 21 of Example 2, the diffusion of Ti in the lower Ti layer 23d is prevented because the Cu layer 23c is disposed between the first metal layer 23b and the lower Ti layer 3d. This enables the rate of change in frequency of the acoustic wave device 21 of Example 2 to be greatly reduced and minimized during the dielectric strength test. Therefore, the frequency characteristic of the acoustic wave device 21 of Example 2 is prevented from being deteriorated during the dielectric strength test. This enables the acoustic wave device 21 of Example 2 to have excellent dielectric strength.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate; and
an IDT electrode disposed on the piezoelectric substrate; wherein
the IDT electrode includes a metal laminate;
the metal laminate includes a first metal layer made of Al or an Al-based alloy, a second metal layer made of a metal or alloy different from that included in the first metal layer, a Cu layer, and a Ti layer;
the Cu layer and the Ti layer are disposed between the first metal layer and the second metal layer; and
the Cu layer is located closer to the first metal layer than the Ti layer.

2. The acoustic wave device according to claim 1, wherein the Al-based alloy primarily includes Al and also includes at least one material selected from the group consisting of Cu, Si, Mg, Ti, Ag, Ni, Zn, Au, and Cr.

3. The acoustic wave device according to claim 1, wherein the second metal layer is made of at least one material selected from the group consisting of Pt, Au, Ag, Ta, W, Mo, Pd, Ni, and Cr or an alloy primarily including at least one of Pt, Au, Ag, Ta, W, Mo, Pd, Ni, and Cr.

4. The acoustic wave device according to claim 1, wherein the Ti layer has a thickness that is about 1.5% or less than a wavelength of an acoustic wave propagating in the acoustic wave device.

5. The acoustic wave device according to claim 1, wherein the acoustic wave device is a surface acoustic wave device.

6. The acoustic wave device according to claim 1, further comprising a dielectric layer extending over the IDT electrode, wherein the acoustic wave device is arranged to function as a boundary acoustic wave device utilizing a boundary acoustic wave propagating along an interface between the dielectric layer and the piezoelectric substrate.
